(19) United States
(12) Patent Application Publication
(10) Pub. No.: US 2023/0420912 A1
(43) Pub. Date: Dec. 28, 2023

(54) Optical Transmitter

(71) Applicant: Nippon Telegraph and Telephone Corporation, Tokyo (JP)

(72) Inventors: Meishin Chin, Musashino-shi, Tokyo (JP); Shigeru Kanazawa, Musashino-shi, Tokyo (JP); Takahiko Shindo, Musashino-shi, Tokyo (JP)

(21) Appl. No.: 18/252,931

(22) PCT Filed: Nov. 20, 2020
(86) PCT No.: PCT/JP2020/043392

§ 371 Date: May 15, 2023

(51) Int. Cl. H01S 5/026; H01S 5/00; G02B 6/293; G02B 6/42; H04B 10/54

(52) U.S. Cl. CPC H01S 5/0265; H01S 5/0085; G02B 6/29344; G02B 6/4215; H04B 10/54; H01S 5/12

(57) ABSTRACT

An optical transmitter of the present disclosure is obtained by integrating a DFB laser, an EA modulator, and SOAs, and intensity-modulated light from the EA modulator is optically amplified in the parallelized SOAs. The parallelized SOAs include a first MMI that splits the intensity-modulated light from the EA modulator toward two or more optical paths, corresponding SOAs that optically amplify the split light, and a second MMI that combines the optically amplified lights. The components of the optical transmitter are integrated on a single substrate. In the parallelized SOAs, it is possible to obtain a higher output power and an improved waveform quality, by applying a total SOA injection current that is the same as that of an optical transmitter of a conventional technology including a single SOA.

### TECHNICAL FIELD

The present invention relates to an optical transmitter in which a laser, an optical modulator, and optical amplifiers are integrated.

### BACKGROUND ART

With the recent spread of video distribution services and the increasing demand for mobile traffic, network traffic is drastically increasing. In an optical transmission line that supports a network, a network cost reduction through an extension of a transmission distance, in addition to an increase in transmission rate and a reduction in power consumption, has become a trend. There also is an increasing demand for higher speed and higher output for semiconductor modulated light sources that are used in optical transmission lines.

Distributed feedback (DFB) lasers in which an electro-absorption (EA) modulator is integrated in the same chip (these lasers will be hereinafter referred to as EADFB lasers) have been used in a wide variety of applications. A DFB laser includes an active layer having a multiple quantum well (MQW), and oscillates with a single wavelength by a diffraction grating formed in a resonator. Meanwhile, an EA modulator includes a light absorption layer formed with a MQW having a composition different from that of a DFB laser, and changes the light absorption amount through voltage control. Driving under transmission or absorption conditions causes the output light from the DFB laser to turn on and off, and transform information on an electrical signal into a modulated optical signal.

While an EADFB laser has high extinction characteristics and excellent chirping characteristics, the difficulty in increasing outputs due to the optical loss accompanying the EA modulator is one of the problems. As a solution to this problem, an EADFB laser in which a semiconductor optical amplifier (SOA) is further integrated at the light emitting end of the EADFB laser has been suggested. A form of an optical transmitter in which an EADFB laser and an SOA are integrated is also called a SOA assisted extended reach EADFB laser (AXEL) (Non Patent Literature 1).

FIG. 1 is a schematic view of a configuration of an AXEL in which an EADFB laser and an SOA are integrated. In an AXEL 100 in FIG. 1, a laser unit 101, an EA modulator 102, and a SOA unit 103 are integrated on a single semiconductor substrate. FIG. 1 is a conceptual diagram of an AXEL viewed perpendicularly to the substrate surface (x-z plane), and the three portions 101, 102, and 103 are in the form of an optical waveguide continuous in the z direction. A laser drive current IUD 106 is supplied to the laser unit 101, and an injection current (hereinafter referred to as the SOA current I_{soA}, 107) is supplied to the SOA unit 103.

In the AXEL, signal light modulated by the EA modulator is amplified in the integrated SOA region, and output light 105 having power that is twice higher than that of a general EADFB laser is obtained. In the case of driving under operating conditions with which the same optical output as that of a general EADFB laser can be obtained, the power consumption by the AXEL can be lowered by about 40%, because of the high-efficiency operation achieved through the SOA integration. In the AXEL, the same MQW structure as that of a DFB laser is used for the active layer of the SOA. Accordingly, device manufacturing can be performed through the same manufacturing process as that for an EADFB laser of a conventional technology, without addition of a regrowth process for SOA region integration.

### CITATION LIST

### Non Patent Literature

Non Patent Literature 1: W Kobayashi et al., “Novel approach for chirp and output power compensation applied to a 40-Gbit/s EADFB laser integrated with a short SOA,” April 2015 Opt. Express, Vol. 23, No. 7, pp. 9533-9542

### SUMMARY OF INVENTION

### Technical Problem

Although the AXEL in which a SOA and an EADFB laser are integrated can obtain a higher output than that of a conventional EADFB laser (hereinafter referred to simply as an EADFB), there is a fundamental problem in achieving even higher outputs. The cause of hindering an increase in output is gain saturation due to induced emission in the SOA. The gain saturation means that the amplification gain of the SOA decreases as the power input to the SOA increases. When gain saturation occurs, carrier consumption due to induced emission exceeds the supply, and carriers in the active layer are depleted. Here, attention is paid to the SOA operation in the light propagating direction (z direction) in the SOA unit 103 in FIG. 1. As signal light propagates in the optical waveguide of the SOA unit 103 in the z direction and is subjected to power amplification, the gain becomes smaller at portions closer to the SOA terminal due to the above-mentioned carrier depletion. As a result of the gain decrease in the z direction, the optical amplification is reduced when viewed from the entire SOA, and the increase in output is restricted.

A problem that occurs in association with gain saturation is a signal waveform degradation phenomenon called a pattern effect. In a case where a baseband signal has a Non-Return-to-Zero (NRZ) signal format, bit 1 corresponds to a case where light input from the EA modulator 102 to the SOA unit 103 is strong, and bit 0 corresponds to a case where the EA modulator 102 is almost in an extinguished state. The carrier consumption in the SOA varies in each bit state, and it takes a certain time for the consumed carriers to be resupplied and reinforced. Therefore, the carrier consumption state of the SOA varies depending on the signal continuity of bit 1 and the frequency of bit 1, and the total gain of the SOA also varies. Due to the pattern effect in which the gain of the SOA varies depending on the bit arrangement, the light intensity of the bit-1 signal varies, the extinction ratio of the eye pattern waveform of the decoded signal decreases, and the eye opening becomes narrower.

Referring back to FIG. 1, an increase in the SOA current 107 (I_{soA}) injected into the SOA can alleviate the influence of gain saturation in the SOA unit 103. However, in a state where the SOA current I_{soA}, is large, the device generates heat, and the light emission efficiency drops due to a temperature rise. In addition to gain saturation, the temperature rise also limits the output power 105 from the AXEL.

FIG. 2 is a graph illustrating the relationship between the SOA injection current and the AXEL output power. With the power (3 mW and 6 mW) input to the SOA being the parameter, the abscissa axis indicates the SOA current I_{soA}, (mA), and the ordinate axis indicates the output power (mW) from the AXEL. A comparison between the two curves different in the power input to the SOA shows that the output power is about 1.4 times higher, though the power input to the SOA is doubled. This is due to the above-described gain saturation in the SOA. Further, in the region where the SOA current I_{soA}, is high in FIG. 2, the SOA output power, which is the output power of the AXEL, reaches its peak and saturates, even if the SOA current to be injected is increased. The saturation of the output power at the time of the high SOA current is affected by gain saturation of the SOA and heat generation from the device.

As described above, in an optical transmitter having an AXEL configuration, there is a problem of degradation of waveform quality due to limitations on increases in high outputs and a pattern effect. The present invention has been made in view of such problems, and provides an optical transmitter that achieves a higher output and an improved waveform quality.

### Solution to Problem

An embodiment of the present invention is an optical transmitter comprising: a laser for outputting continuous light; an EA modulator for performing intensity modulation on the continuous light; a first multi-mode interference waveguide (MMI) that splits the intensity-modulated light toward at least two optical paths; semiconductor optical amplifiers (SOAs) for optically amplifying the corresponding light being split into at least two; and a second MMI that for combining the lights being amplified in the at least two optical paths, wherein the laser, the EA modulator, the first MMI, the corresponding SOAs, and the second MMI are integrated on a single substrate.

### Advantageous Effects of Invention

The present invention is to achieve a higher power output and an improved waveform quality of an optical transmitter.

### BRIEF DESCRIPTION OF DRAWINGS

FIG. 1 is a schematic view of a configuration of an AXEL in which an EADFB laser and an SOA are integrated.

FIG. 2 is a graph illustrating the relationship between an SOA injection current and AXEL output power.

FIG. 3 is a diagram illustrating the configuration of a first embodiment of an optical transmitter of the present disclosure.

FIG. 4 is a diagram for explaining a beam pattern of light propagating in a MMI.

FIG. 5 is a diagram illustrating a beam pattern of light in each cross-section of light propagating in a MMI.

FIG. 6 is a diagram illustrating a specific configuration of a SOA unit according to the first embodiment.

FIG. 7 is a graph illustrating the laser drive current and output power characteristics in an AXEL according to a conventional technology.

FIG. 8 is a graph illustrating the SOA current dependency of output power of an optical transmitter of the present disclosure.

FIG. 9 is a diagram illustrating eye patterns of decoded outputs from the optical transmitter of the present disclosure.

FIG. 10 is diagrams of two-dimensional temperature distribution simulations of X-Y cross-sections in SOAs.

FIG. 11 is a diagram illustrating comparisons among one-dimensional temperature distributions in the core width direction in SOAs.

FIG. 12 is a diagram illustrating a specific configuration of a SOA unit according to a second embodiment.

FIG. 13 is a diagram illustrating a beam pattern of light propagating in MMIs of the second embodiment.

### DESCRIPTION OF EMBODIMENTS

An optical transmitter of the present disclosure is obtained by integrating a DFB laser, an EA modulator, and SOAs, and intensity-modulated light from the EA modulator is optically amplified in the parallelized SOAs. The parallelized SOAs include a first multi-mode interference (MMI) that splits the intensity-modulated light toward two or more optical paths, corresponding SOAs that optically amplify the split light, and a second MMI that combines the optically amplified lights. There may be three or more parallelized SOAs. The components of the optical transmitter are integrated on a single substrate. In the parallelized SOAs, it is possible to obtain a higher output power and an improved waveform quality even with a total SOA injection current that is the same as that of an optical transmitter of a conventional technology including a single SOA. On the other hand, when the same SOA injection current is supplied, the temperature rise in the SOAs is reduced, and the influence of the gain decrease in the SOAs becomes smaller. In the description below, embodiments of optical transmitters of the present disclosure will be explained with reference to the drawings.

### First Embodiment

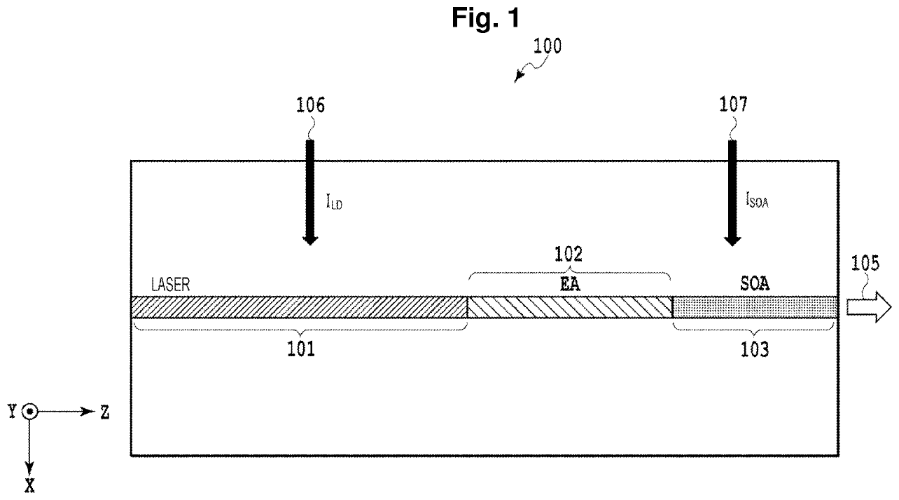

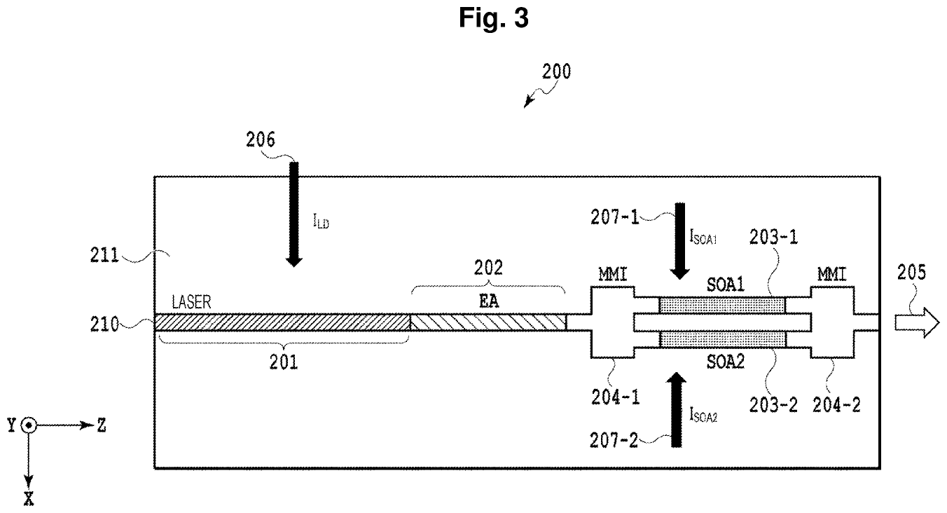

FIG. 3 is a diagram illustrating the configuration of an optical transmitter according to a first embodiment. An optical transmitter 200 in FIG. 3 is a schematic view of a substrate surface (x-z plane) of an AXEL in which a laser unit 201, an EA modulator 202, and SOAs are integrated on a substrate. The optical transmitter 200 is the same as the configuration of the conventional technology illustrated in FIG. 1, in including the laser unit 201 that emits light serving as the source of signal light, and the EA modulator 202 that modulates the intensity of laser emission light. A difference from the AXEL of the prior art illustrated in FIG. 1 lies in the configuration of the SOA, and in including multi-mode interference waveguides, which are MMI waveguides, and a plurality of SOAs. In the description below, the MMI waveguides will be referred to as the MMIs for simplicity.

The SOA of the optical transmitter 200 in FIG. 3 includes a first MMI 204-1 that splits modulated signal light toward two optical paths, a first SOA unit 203-1 and a second SOA unit 203-2 each of which optically amplifies the split light, and a second MMI 204-2 that combines the amplified lights. Although not illustrated in FIG. 3, the optical transmitter 200 also includes a power supply that drives active elements from the laser to the SOA involved in a light amplifying or absorbing operation, and a temperature control device for controlling the temperature of each component. Each of the components from the laser unit to the second MMI has an optical waveguide structure that confines light and causes the light to propagate in one direction, and includes a core portion 210 and a cladding portion 211.

Signal light modulated with a baseband signal at the EA modulator 202 is optically amplified by the SOAs, and output light 205 is obtained from the second MMI 204-2. A laser drive current I_{LD} 206 is supplied to the laser unit 201, and SOA currents I_{soA1} 207-1 and I_{soA2} 207-2, which are injection currents, are supplied to the two SOA units 203-1 and 203-2, respectively.

Unlike the configuration of the conventional technology illustrated in FIG. 1, the optical transmitter of the present disclosure includes a plurality of parallelized SOAs. To input modulated light to the two SOAs, the first MMI 204-1 that splits modulated light from the EA modulator 202 toward two optical paths at a power ratio of 1:1 is provided in the optical transmitter 200 in FIG. 3. The MMI increases the waveguide width from the optical waveguide on the input side to put the propagating light into multiple modes, and generates a characteristic beam pattern in a plane perpendicular to the propagating direction through interference between the multiple modes. A narrow waveguide including the corresponding SOAs is provided in accordance with the beam pattern to be generated by the MMI, and the beams split toward two optical paths are recombined into a narrow waveguide.

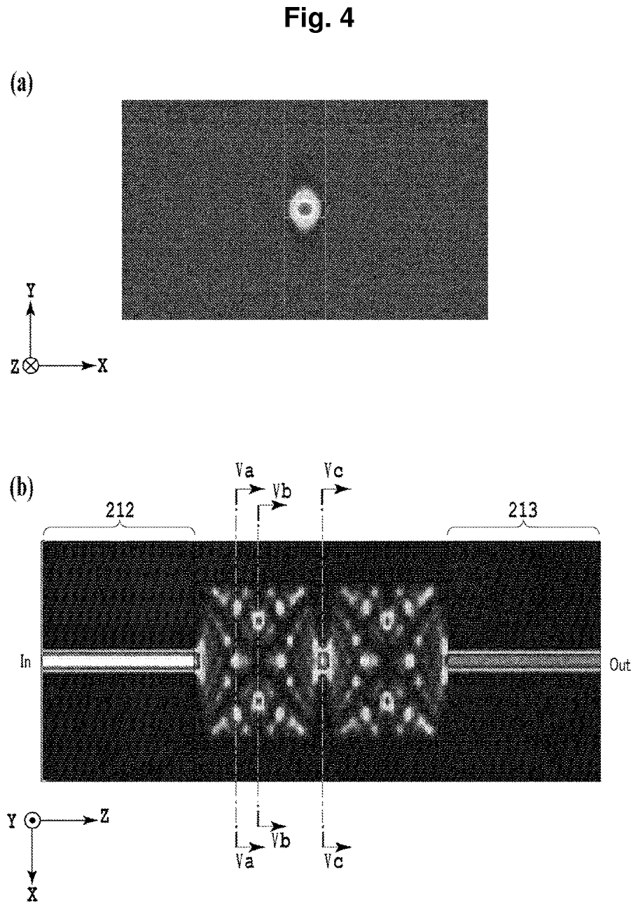

FIG. 4 is a diagram for explaining a beam pattern of light propagating in a MMI. FIG. 4(a) illustrates a beam pattern in a core cross-section (x-y plane) perpendicular to the light propagating direction (z-axis) in an optical waveguide 212 on the input side of the MMI. FIG. 4(b) illustrates a beam pattern when the substrate surface (x-z plane) on which the MMI is formed is viewed. FIG. 4(a) is analyzed by a finite difference method, and FIG. 4(b) is analyzed by a beam propagation method (BPM). In FIG. 4(b), the MMI is in a rectangular region between the input waveguide 212 and an output waveguide 213, and is a one-input and one-output MMI.

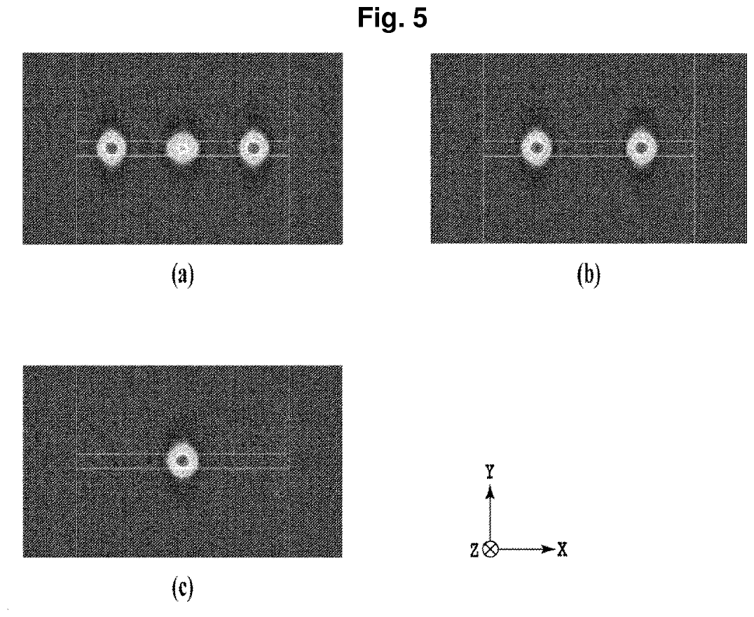

FIG. 5 is a diagram illustrating a beam pattern of light in each cross-section of light propagating in a MMI. FIGS. 5(a), 5(b), and 5(c) illustrate beam patterns in cross-sections (x-y plane) perpendicular to the light traveling direction (z-axis) in the MMI, taken along the line Va-Va, the line Vb-Vb, and the line Vc-Vc in FIG. 4(b). The cross-sections in FIGS. 5(a) to 5(c) illustrate that the power of incident beams from the input waveguide 212 is condensed at three points, two points, and one point, respectively. This pattern is bilaterally symmetrical with respect to the Vc-Vc line. For example, the waveguide 213 that is the same as an incident waveguide is disposed at a symmetrical position of the end position of the input waveguide 212 serving as the point of entry to the MMI, the symmetrical position being symmetrical with respect to the Vc-Vc line. Thus, a single-mode beam can be extracted. Further, waveguides are disposed at the condensing points in the respective cross-sections in FIGS. 5(a), 5(b), and 5(c), so that optical power can be coupled to the three waveguides, two waveguides, and one waveguide, respectively. In the first MMI 204-1 of the optical transmitter in FIG. 3, two optical waveguides connected to the corresponding SOAs are disposed at the output points corresponding to FIG. 5(b), and light modulated by an EA modulator is branched toward two optical paths. By this branching, the optical power entering each of the two SOA units 203-1 and 203-2 is halved, compared with that in a case where a single SOA of a conventional technology is used.

As for a more specific configuration of the optical transmitter 200 in FIG. 3, the lengths of the laser unit 201, the EA modulator 202, and the SOA units 203-1 and 203-2 are 300 μm, 200 μm, and 250, respectively. Further, the width of the optical waveguide from the laser unit 201 to the first MMI 204-1 is 1.7 μm. Next, a more specific configuration of the SOA unit in the optical transmitter in FIG. 3 is described.

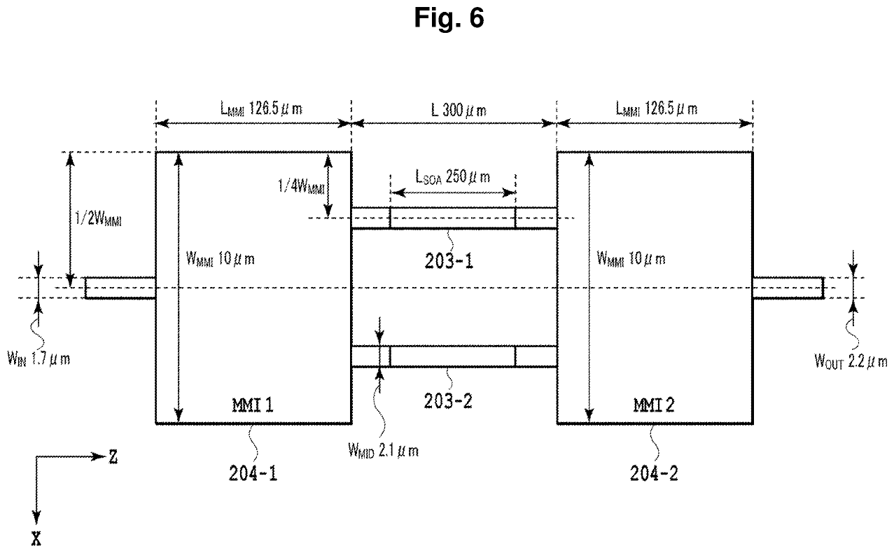

FIG. 6 is a diagram illustrating a specific configuration of the SOA unit according to the first embodiment. It should be noted that the pattern shape illustrated in FIG. 6 has a scale significantly different between the width direction (x direction) and the length direction (z direction) of the optical waveguide, and is illustrated in an enlarged manner in the width direction. The two MMIs 204-1 and 204-2 connect the respective branched ports with two branched optical paths including the corresponding SOA units 203-1 and 203-2. Each of the optical waveguides of the branched optical paths including the SOAs and the optical waveguide leading to the second MMI 204-2 is slightly wider than the optical waveguide of the preceding portion. This is a structure for minimizing the transmission loss in the two MMIs 204-1 and 204-2, and is in the form of an optical waveguide with an optically minimum loss. Specifically, the waveguide width of each portion is W_{IN}=1.7 μm on the input side of the first MMI 204-1, W_{MID}=2.1 μm in the SOAs, and W_{OUT}=2.2 μm on the output side of the second MMI 204-2.

Waveguide structures that are normally used in semiconductor lasers are ridge waveguides, buried waveguides, or high-mesa waveguides. A ridge waveguide has an active layer of a slab structure, and a layer above the region corresponding to the core is formed with a semiconductor. The layer above the cladding region is replaced with air or a low refractive index material such as benzocyclobutene (BCB), so that a waveguide is formed, and light is confined in the core. A buried waveguide is formed by processing an active layer into a mesa shape by etching or the like, and filling both sides of the mesa with a low refractive index semiconductor material. A high-mesa waveguide is formed by performing mesa processing on an active layer in the same manner as for a buried waveguide, and performing burying with air or BCB, instead of a semiconductor material.

In the optical transmitter of the first embodiment illustrated in FIGS. 3 and 6, each waveguide is formed with the above-described ridge waveguide, but the other waveguide structures described above can also be used in manufacturing an optical transmitter. Further, the MMIs can be high-mesa structures, the SOAs can be buried structures, and the different waveguide structures can be combined to manufacture an optical transmitter. In a case where the SOAs are buried structures, the distance between the mesas of the waveguides of the two SOAs might become narrower in the adjacent branched optical paths. At this stage, the conditions for buried growth between the two mesas differ from the growth conditions outside the mesas, and it might be difficult to grow a buried layer between the mesas. In such a case, it is preferable to form a structure in which the distance between the waveguides of the optical paths constituting the SOAs is 1 μm or longer. The distance between the two optical paths (optical waveguides) including the corresponding SOAs is determined by the waveguide width Wm′ of the two MMIs 204-1 and 204-2, and can be controlled through adjustment of the design of the MMIs.

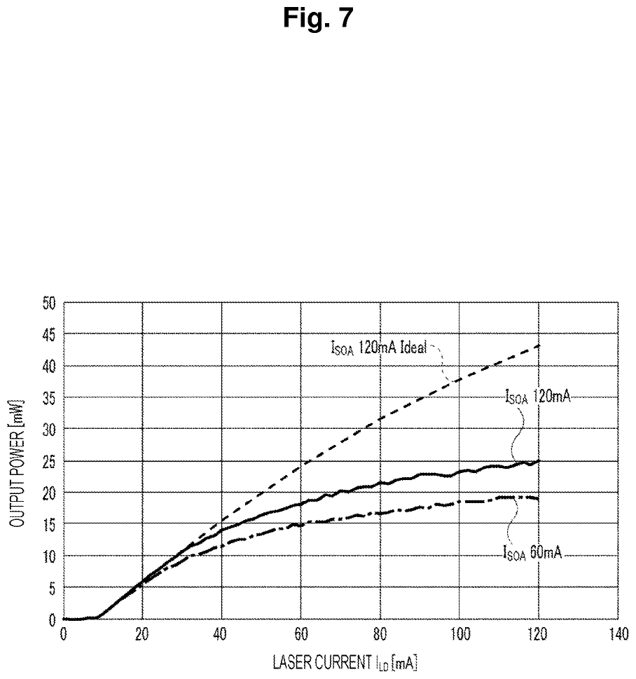

FIG. 7 is a graph illustrating the laser drive current and output power characteristics in an AXEL according to the conventional technology. For the AXEL having the configuration of the conventional technology into which a single SOA is integrated as illustrated in FIG. 1, the abscissa axis indicates the laser drive current I_{LD} (mA), and the ordinate axis indicates the output power characteristics (mW), with the SOA current I_{soA}, being the parameter. Except for not involving any MMI, the conditions for designing and the method for manufacturing active elements related to light emission and the like in the AXEL of the conventional technology are similar to those for the optical transmitter of the present disclosure illustrated in FIG. 3. The lengths of the respective components in the optical waveguide direction are 300 μm, 200 μm, and 250 μm in the order of the laser, the EA, and the SOA.

In FIG. 7, the laser drive current I_{LD} on the abscissa axis can be regarded as the output power PLD from the laser unit. In a case where gain saturation does not occur in ideal SOAs, and optical amplification is performed with a constant gain not depending on the power input to the SOAs, the I_{LD}-output power characteristics are substantially represented by a straight line indicated by a dotted line shown as 120 mA Ideal. The reason why the I_{LD}-output power characteristics obtained when amplification is performed by ideal SOAs are not a straight line but a slightly curved line in FIG. 7 is that the characteristics of the drive current IUD and the output power PLD in the laser are not linear, but reflect the nonlinearity of the I_{LD}-PLD characteristics.

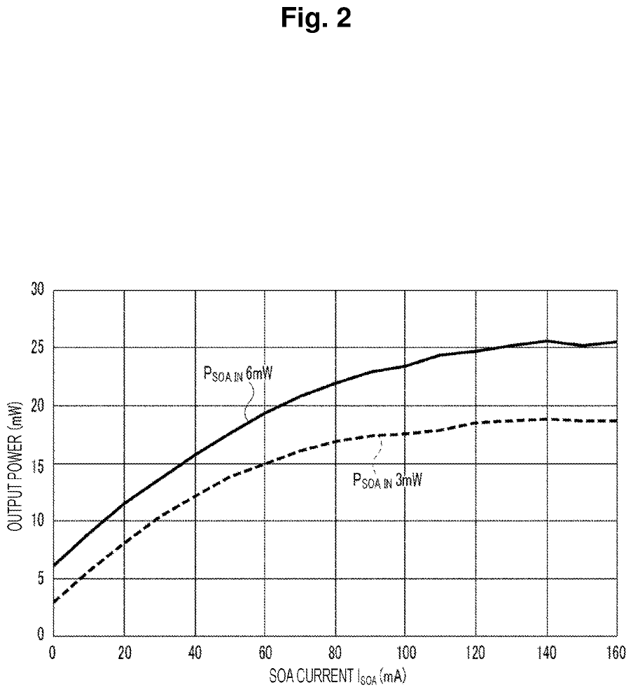

In either of the cases of the two SOA currents (60 mA and 120 mA) illustrated in FIG. 7, the deviation from the dotted ideal curve becomes greater, as the laser drive current I_{LD}, which is the power input to the SOA, becomes higher. It can be seen that, in the actual AXEL, even if large power is input to the SOA, sufficient optical amplification cannot be performed due to gain saturation of the SOA. The saturation of the output of the AXEL with respect to the laser drive current I_{LD} illustrated in FIG. 7 corresponds to the phenomenon of peaking of the output power of an AXEL with respect to increases in the power input to the SOA, which has been described as a problem of the conventional technology with reference to FIG. 2.

In the optical transmitter 200 of the present disclosure illustrated in FIG. 3, the modulated output from the EA modulator 202 is branched toward two optical paths by the first MMI 204-1 on the input side of the SOAs. In a case where the drive current IUD of the laser is 120 mA, the output power from the EA modulator is 6 mW. As a result of a numerical calculation simulation, the total power transmittance of the first MMI 204-1 including the two branch portions is 93%. In a case where the drive current IUD of the laser is 120 mA, the power input to each of the SOA units 203-1 and 203-2 is 2.8 mW.

Also, as a result of a numerical calculation simulation, the total power transmittance of the second MMI 204-2 is 97%. When the amplified two modulated light beams are combined again in the second MMI 204-2, the phases of the light beams passing through the two optical waveguides including the SOAs need to be the same. In the optical transmitter 200 in FIG. 3, the optical paths between the first MMI and the second MMI includes the corresponding SOAs, and have the same optical length. The amplified two modulated light beams are originally obtained by splitting a single light beam, and the split optical waveguides have the same shape, so as to be in the same phase.

In a case where there is a possibility of the occurrence of a phase shift due to a slight difference in amplification conditions in the two SOA units 203-1 and 203-2, a mechanism for performing phase adjustment can be added. That is, an adjustment unit that applies an electric current for independently adjusting the optical length can be provided in the optical paths between the first MMI and the second MMI. For example, in the two optical waveguides between the pair of MMIs 204-1 and 204-2, a phase adjustment unit capable of current injection can be provided in at least one of the paths at the portions excluding the SOA regions. Phase adjustment can be performed by adjusting the current injection amount at these phase adjustment units, to minimize the loss at the time of combining in the second MMI 204-2.

Instead of providing the phase adjustment unit mentioned above, at least one of the injection current amounts flowing into the two SOAs can be adjusted, and adjustment can also be performed to maximize the output power after the combining in the second MMI 204-2. This adjustment mechanism takes advantage of the fact that a change in the injection current into the SOAs also changes the phase of light output from the SOAs.

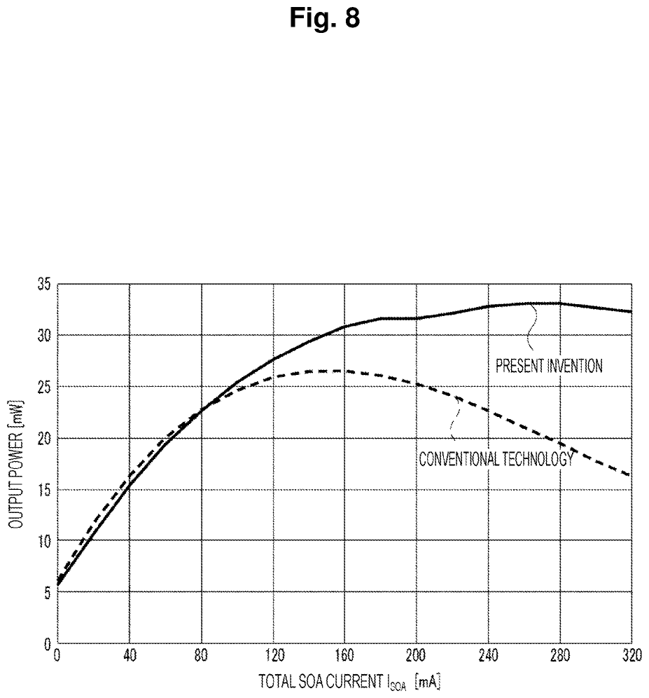

FIG. 8 is a graph illustrating the SOA current dependency of the output power of the optical transmitter of the present disclosure. The abscissa axis indicates the total SOA current I_{soA}, (mA), and the ordinate axis indicates the output power (mW) of the output light 205 from the optical transmitter. The SOA current dependency of the output power 105 of the optical transmitter 100 having the structure of the conventional technology illustrated in FIG. 1 is also illustrated. The laser drive current IUD is 120 mA. As can be seen from FIG. 8, in a case where the SOA current is increased in the optical transmitter of the conventional technology, the slope of the curved line becomes gradually gentler from around 80 mA, and the output power starts decreasing when the SOA current reaches 140 mA. As described above, the output saturation and decrease were caused by a complex combination of factors such as heat generation and carrier overflow, and an output power higher than 30 mW was not obtained even when the SOA current is increased. On the other hand, in the optical transmitter of the present disclosure, the output power did not decrease, and an output power of 33 mW at maximum was obtained, though the output power tended to saturate.

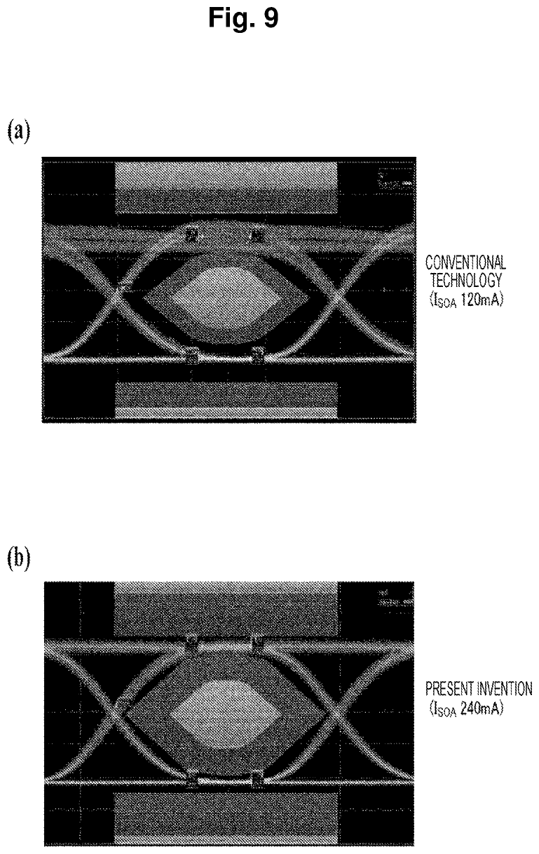

FIG. 9 is a diagram illustrating eye patterns of decoded outputs of the optical transmitter of the present disclosure. FIG. 9(a) illustrates an eye pattern of output light when the SOA current I_{soA}, is 120 mA and the output power is 26 mW in the optical transmitter of the conventional technology. FIG. 9(b) illustrates an eye pattern of output light when the total SOA current I_{soA}, is 240 mA and the output power is 33 mW in the optical transmitter of the present disclosure. In the case of the conventional technology, the extinction ratio is 10 dB, and the mask margin is 50%. In the optical transmitter of the present disclosure, on the other hand, the extinction ratio is 13 dB, and the mask margin is 80%. A comparison between the eye patterns illustrated in FIG. 9 shows that the waveform quality is improved in the optical transmitter of the present disclosure including the parallelized SOAs even with an output power higher than that in the case of the conventional technology.

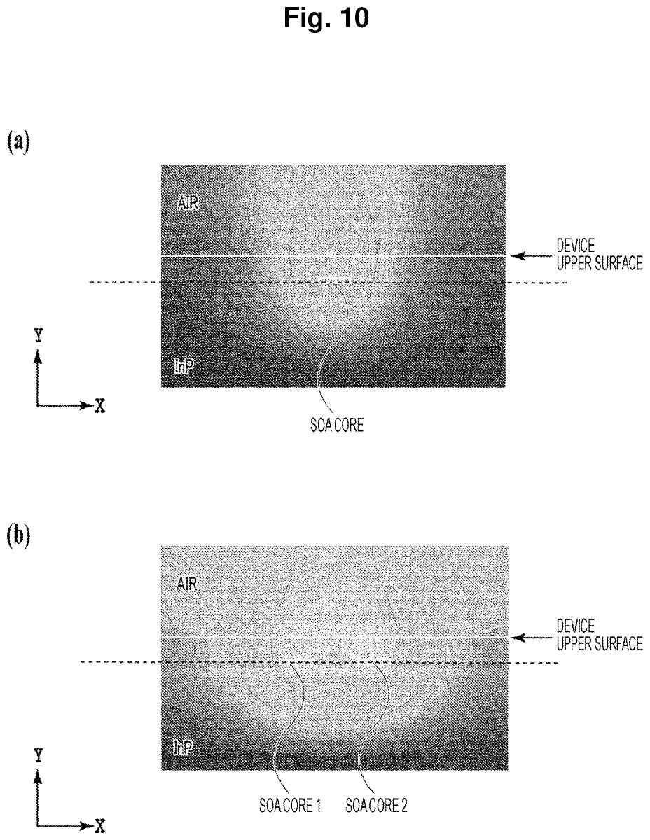

FIG. 10 is a diagram illustrating a result of a two-dimensional temperature distribution simulation in the SOAs of the optical transmitter of the present disclosure. FIG. 10(a) illustrates a temperature distribution in a cross-section (x-y plane) perpendicular to the light propagating direction in the SOA core in the case of the single SOA of the conventional technology. FIG. 10(b) illustrates the same temperature distribution in the two SOA cores in the optical transmitter of the present disclosure. In either case, there is the SOA core(s) on a dotted line, and the upper surface of the device is indicated by an arrow. The substrate was an InP substrate, and the simulations were performed on the assumption that air existed above the upper surface of the device. Here, the heat generation amount at each SOA core is assumed to be mW/mm with heat generation per volume of 1 mm in the waveguide direction in the cross-sectional area of the SOA core, and the room temperature is assumed to be 27° C.

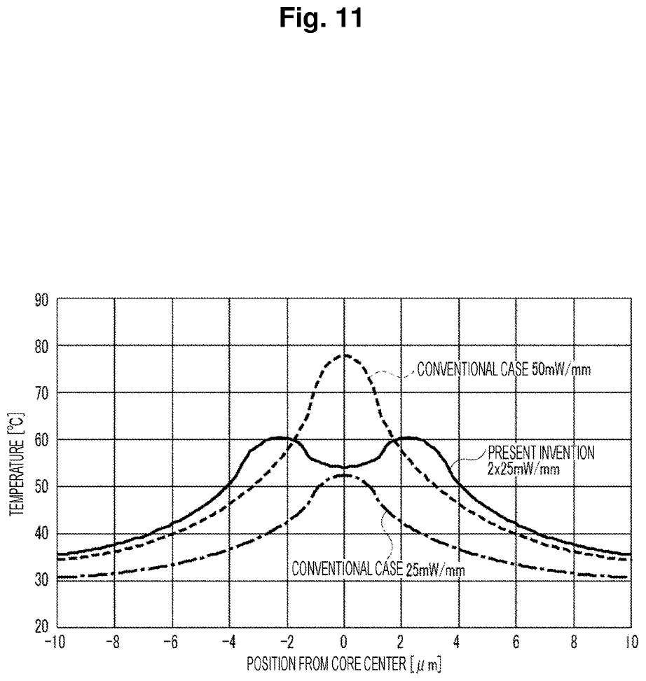

FIG. 11 is a diagram illustrating comparisons among one-dimensional temperature distributions in the core width direction in SOAs. The temperature distributions in FIG. 11 indicate one-dimensional temperature distributions in the width direction of the core along the dotted line (x-axis) in FIG. 10. The abscissa axis indicates the position (μm) from the center of the core in the x-axis direction, and the ordinate axis indicates temperature (° C.). In a case where the amount of heat generation at the SOA core is 25 mW/mm in the structure with a single SOA of the conventional technology, the temperature at the center position of the core is about 52° C. The temperature rise range at the center of the core is with respect to room temperature. On the other hand, in a case where the amount of heat generation is 25 mW/mm at each of the two SOA cores 1 and 2 in the optical transmitter of the present disclosure, the temperature at the center position of each core is about 60° C. The temperature rise range at the center of the core is 33° C. with respect to room temperature.

Here, the above-described two curves in a case where the injection current in each SOA core is the same are compared. Compared with the conventional optical transmitter having a single SOA, the optical transmitter 200 of this embodiment has two SOAs in parallel, and thus, the temperature rise range is about 32% wider. In the meantime, comparison is made in a case where the total SOA current is the same. That is, temperature rises in a case where the SOA core of the optical transmitter of the conventional technology generates heat at 50 mW/mm are now described. In the heat generation at 50 mW/mm with a single SOA, the temperature of the SOA core at this point of time increases to 78° C., as illustrated in FIG. 11. The temperature rise range from the room temperature of 27° C. is 51° C. Therefore, it can be seen that, in the optical transmitter of the present disclosure, the temperature rise range in a case where the total SOA current is the same can be reduced to about 64% (−36%) of that with the conventional technology.

As explained in the description of the SOA current dependency of output power illustrated in FIG. 8, even if the total SOA current is 240 mA, for example, the output level to be obtained is much higher in the optical transmitter of the present disclosure. On the other hand, from the point of the temperature distribution illustrated in FIG. 11, it is clear that, when comparison is made on the assumption that the total SOA current is the same, the optical transmitter of the present disclosure can reduce the temperature rise more efficiently than the configuration of the conventional technology. It is shown that the optical transmitter including the parallelized SOAs of the present disclosure is less likely to be affected by a decrease in output power due to heat generation in the device in a case where the total SOA current is the same.

As the optical transmitter of the present disclosure includes the parallelized SOAs as described above, an output level higher than that with the conventional technology can be obtained under the same SOA current conditions, and at the same time, an improved waveform quality can be achieved. When comparison is made in a state where the SOA current is the same, the temperature rise at the SOA cores is reduced, though a higher output level can be obtained. Also, the optical transmitter is hardly affected by a decrease in output power due to heat.

Although the optical transmitter includes two SOAs in parallel in the example configuration of the optical transmitter of the first embodiment described above, it is possible to increase the number of parallelized SOAs by increasing the number of optical paths branching from the EA modulator to three or more.

### Second Embodiment

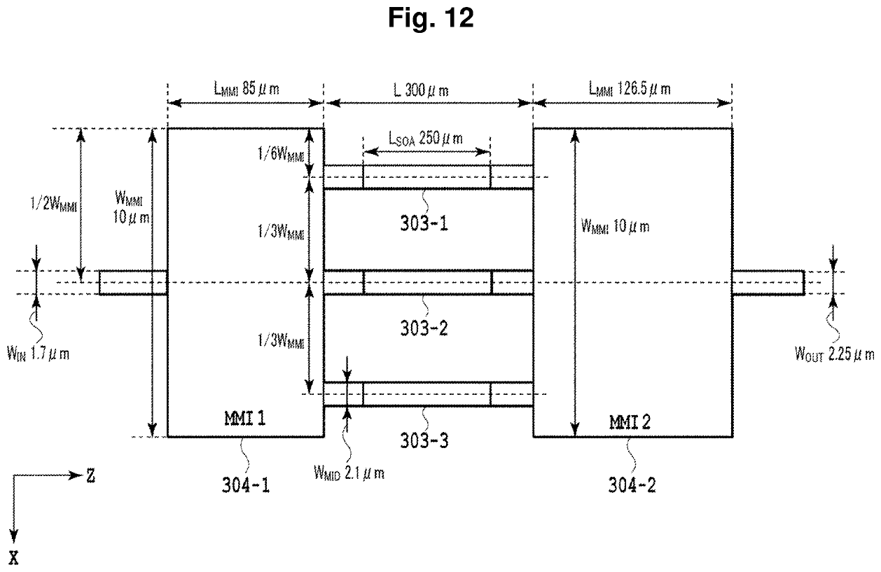

FIG. 12 is a diagram illustrating a specific configuration of a SOA unit according to a second embodiment. An overall configuration of an optical transmitter of the second embodiment is substantially the same as that of the optical transmitter 200 of the first embodiment illustrated in FIG. 3, except that the portion following the EA modulator 202 in FIG. 3 is replaced with the SOA unit illustrated in FIG. 12. A difference from the configuration of the optical transmitter of the first embodiment in FIG. 3 is the EADFB output power setting. In this embodiment, the optical path in the SOA unit branches into three. Therefore, the power input to a SOA becomes lower than the optimum value in the same design as the first embodiment in which the optical path branches into two. To counter this, the laser unit 201 has a greater length of 500 μm. Further, the drive current of the laser unit is set to 200 mA. As illustrated in FIG. 12, between two MMIs 304-1 and 304-2 of the three-branch configuration, three paralleled optical paths that are formed with optical waveguides including SOAs 303-1 to 303-3, and have the same optical length are provided. The lengths of the first MMI 304-1 and the second MMI 304-2 in the waveguide direction (z direction) are different, being 85 μm and 126.5 μm, respectively.

Each of the optical waveguides of the three branched optical paths including the corresponding SOAs and the optical waveguide leading to the second MMI 304-2 is slightly wider than the optical waveguide of the preceding portion. Specifically, the waveguide width of each portion is W_{IN}=1.7 μm on the input side of the first MMI 304-1, W_{MID}=2.1 μm in the SOAs 303-1 to 303-3, and W_{OUT}=2.25 μm on the output side of the second MMI 304-2. As in the first embodiment, a structure for minimizing the transmission loss in the two MMIs 304-1 and 304-2 is adopted, and the components from the laser unit to the output waveguide of the second MMI are designed in the form of an optical waveguide having the optically minimum loss.

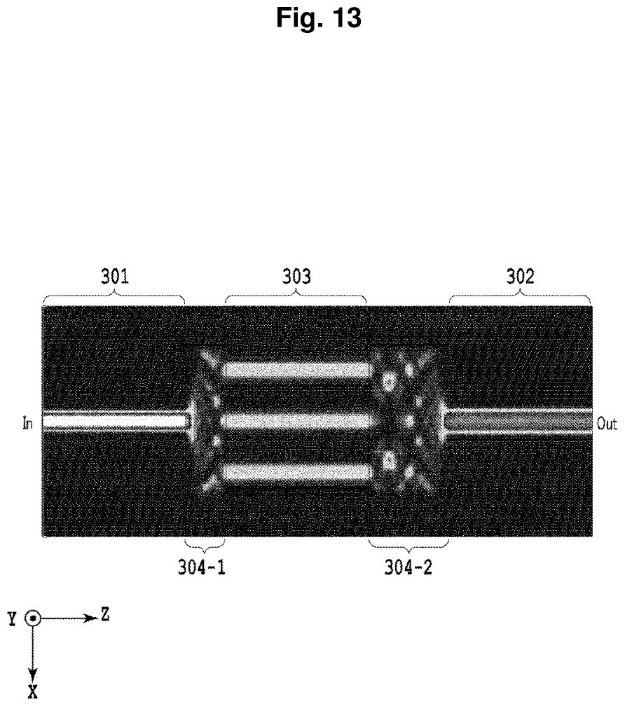

FIG. 13 is a diagram illustrating a beam pattern of light propagating in the MMIs of the optical transmitter of the second embodiment. This drawing shows a beam pattern at a time when the substrate surface (x-z plane) having the MMIs formed thereon is viewed, and corresponds to FIG. 4(b) of the first embodiment. The beam pattern shown in FIG. 13 is also analyzed by a BPM method as in FIG. 4(b). A beam that has entered an input waveguide 301 is branched toward three optical paths by the first MMI 304-1, and the branched light beams propagate in three optical paths 303 corresponding to the SOAs. The light beams that have propagated through the optical paths 303 are combined into one beam at the second MMI 304-2, and the one beam is output from an output optical waveguide 302. In the configuration with the two MMIs illustrated in FIG. 13, the overall transmittance in a case where there is no gain in the SOAs is 87% as a result of a simulation.

As the MMIs branching into the three optical paths described above, and the three parallelized SOAs were formed, a higher output and improvement in waveform quality were achieved as in the first embodiment. When the total current of the SOA unit was 360 mA, an output power of 43 mW was obtained as the output power of the optical transmitter. The output power was successfully increased by 65% with respect to the maximum output power of 26 mW in the configuration of the conventional technology illustrated in FIG. 8 for comparison. As the waveform quality at this point of time, an extinction ratio of 13 dB was obtained, which is equivalent to the eye pattern of the optical transmitter of the first embodiment illustrated in FIG. 9(b).

As described above in detail, with an optical transmitter of the present disclosure, a higher output level than that with the conventional technology can be obtained under the same SOA current conditions, and at the same time, a higher waveform quality than that with the conventional technology can be achieved. Further, although a higher output level than that with the conventional technology can be obtained, the temperature rise at the SOA cores is reduced, and the influence of a decrease in output power due to heat also becomes smaller. An optical transmitter having the parallelized SOAs of the present disclosure achieves a higher output and an improved waveform quality of a decoded signal, compared with the conventional technology.

### INDUSTRIAL APPLICABILITY

An optical transmitter of the present invention can be used in an optical communication system.

1. An optical transmitter comprising:
a laser for outputting continuous light;
an EA modulator for performing intensity modulation on the continuous light;
a first multi-mode interference waveguide (MMI) that splits the intensity-modulated light toward at least two optical paths;
semiconductor optical amplifiers (SOAs) for optically amplifying the corresponding light being split into at least two; and
a second MMI that for combining the lights being amplified in the at least two optical paths,
wherein the laser, the EA modulator, the first MMI, the corresponding SOAs, and the second MMI are integrated on a single substrate.

2. The optical transmitter according to claim 1, wherein components from the laser to an output waveguide of the second MMI are in the form of an optical waveguide having an optically minimum loss.

3. The optical transmitter according to claim 1, wherein the optical paths between the first MMI and the second MMI include the corresponding SOAs, and have the same optical length.

4. The optical transmitter according to claim 2, wherein a distance between the optical waveguides of the optical paths adjacent to each other is not shorter than 1 μm.

5. The optical transmitter according to claim 1, further comprising,
in the optical paths between the first MMI and the second MMI,
an adjustment unit for applying an electric current to independently adjust optical length.

6. The optical transmitter according to claim 1, wherein at least one of injection currents into the corresponding SOAs is controlled, to maximize output power.

7. The optical transmitter according to claim 1, wherein, among an input waveguide of the first MMI, an output waveguide of the first MMI, and an output waveguide of the second MMI, the input waveguide of the first MMI has the greatest width, the output waveguide of the first MMI has the second greatest width, and the output waveguide of the second MMI has the smallest width.
